(19) United States
(12) Patent Application Publication
(10) Pub. No.: US 2009/0059524 A1
(43) Pub. Date: Mar. 5, 2009

(54) HEAT DISSIPATION DEVICE

(75) Inventors: XUE-WEN PENG, Shenzhen (CN); JUN-HAI LI, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/845,743

(22) Filed: Aug. 27, 2007

(51) Int. Cl. H05K 7/20

(52) U.S. Cl. 361/697; 361/707; 361/709

(57) ABSTRACT

A heat dissipation device (100) includes a vapor chamber (20), a heat sink (10) and a heat pipe (30). The heat sink (10) includes a plurality of fins (12). The heat pipe (30) includes an evaporating portion (32) sandwiched between the vapor chamber (20) and the fins (12) of the heat sink (10), and a condensing portion (34) extending through the fins (12). The vapor chamber (20) is attached to an electronic component (42) mounted on an add-on card (40). The fins (12) of the heat sink (10) directly contact with the vapor chamber (20) and define a recess (127) at a bottom thereof to receive the vapor chamber (20) therein.

### BACKGROUND OF THE INVENTION

1. Field of the Invention

The present invention relates generally to a heat dissipation device, and more particularly to a heat dissipation device having high heat dissipation efficiency.

2. Description of Related Art

It is well known that during operation computer electronic components such as central processing units (CPUs) can generate large amounts of heat. The heat must be quickly removed from an electronic component to prevent it from becoming unstable or being damaged. Typically, a heat sink is attached to an outer surface of the electronic component to absorb heat generated by the electronic component, and the heat absorbed by the heat sink is then dissipated to ambient air.

As the operation speed of the electronic component becomes faster, the heat generated by the electronic component increases to a point where a conventional heat sink is inadequate. In this case, the heat sink needs to be larger to dissipate heat therefrom, but a size of a computer becomes smaller. Thus, a mount of heat generated by the electronic component is accumulated in the computer.

What is needed, therefore, is a heat dissipation device which has a high heat dissipation efficiency to dissipate heat generated by an electronic component.

### SUMMARY OF THE INVENTION

A heat dissipation device includes a vapor chamber, a heat sink and a heat pipe. The heat sink includes a plurality of fins. The heat pipe includes an evaporating portion sandwiched between the vapor chamber and the fins of the heat sink, and a condensing portion extending through the fins of the heat sink. The vapor chamber is attached to an electronic component mounted on an add-on card. The fins of the heat sink directly contact with the vapor chamber and define a recess at a bottom thereof to receive the vapor chamber therein.

Other advantages and novel features will become more apparent from the following detailed description of preferred embodiments when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus and method. Moreover, in the drawings, like reference numerals designate corresponding parts throughout the several views.

FIG. 1 is an exploded, isometric view of a heat dissipation device in accordance with a preferred embodiment of the present invention and a back plate for securing the heat dissipation device to a graphics card;

FIG. 2 is an assembled view of FIG. 1; and

FIG. 3 is a view similar to FIG. 2, but shown from another aspect.

### DETAILED DESCRIPTION OF THE INVENTION

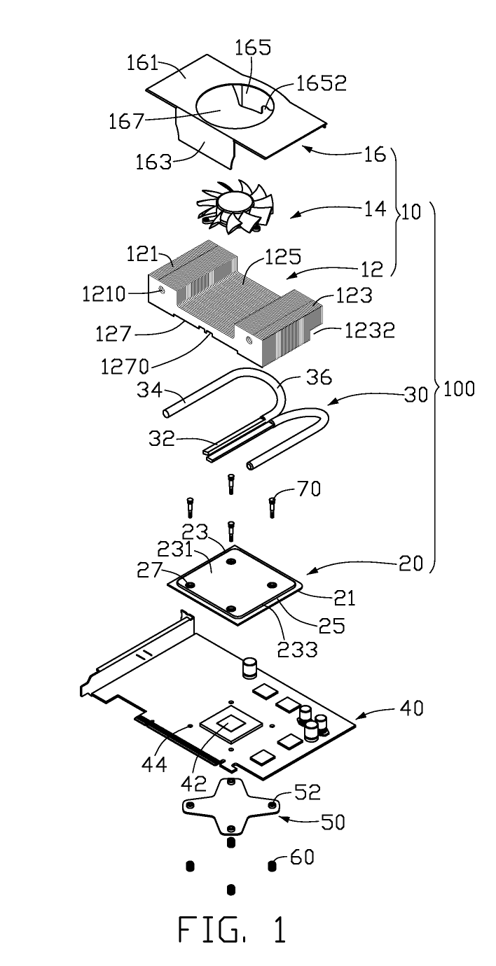

Referring to FIG. 1, an electronic assembly (not labeled) in accordance with the present invention is illustrated, and comprises a graphics card 40, a heat dissipation device 100 mounted on the graphics card 40 adapted for dissipating heat generated by an electronic component 42 mounted on the graphics card 40. The heat dissipation device 100 comprises a heat sink 10, a vapor chamber 20 attached on the electronic component 42 and a pair of heat pipes 30 connecting the heat sink 10 and the vapor chamber 20. The graphics card 40 defines four through holes 44 around the electronic component 42.

The heat sink 10 is located on the vapor chamber 20 and comprises a plurality of parallel fins 12, a fan 14 and a cover 16 mounted onto the fins 12 and covering the fan 14. The fins 12 comprise two shoulders 121, 123 extending upwardly from the opposite ends thereof and a depressed portion 125 located between the shoulders 121, 123. The fan 14 is mounted on the depressed portion 125 of the fins 12. Two flanges (not labeled) perpendicularly extend from the shoulders 121, 123 of each of the fins 12 to contact each other at uniform intervals. The shoulder 123 is cut away at a lower portion at rear end thereof to define a cutout 1232 to prevent the fins 12 from interfering with other electronic components (not labeled) mounted on the graphics card 40. Two channels 1210 are respectively defined at top portions (not labeled) of the shoulders 121, 123 to receive the heat pipes 30. A recess 127 is defined at a bottom surface of the fins 12 to receive and intimate contact with the vapor chamber 20 so as to transfer heat from the vapor chamber 20 to the fins 12. Two adjoining rectangular grooves 1270 are defined at a center of the bottom surface of the fins 12 to receive the heat pipes 30.

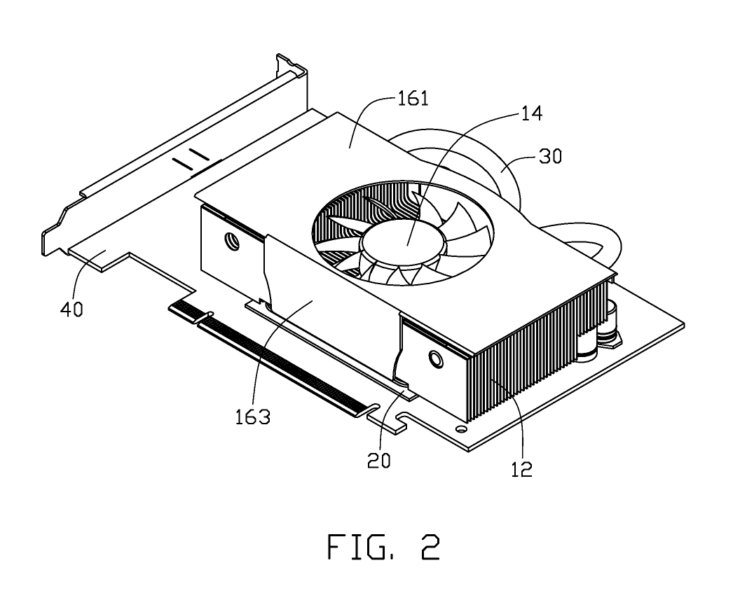

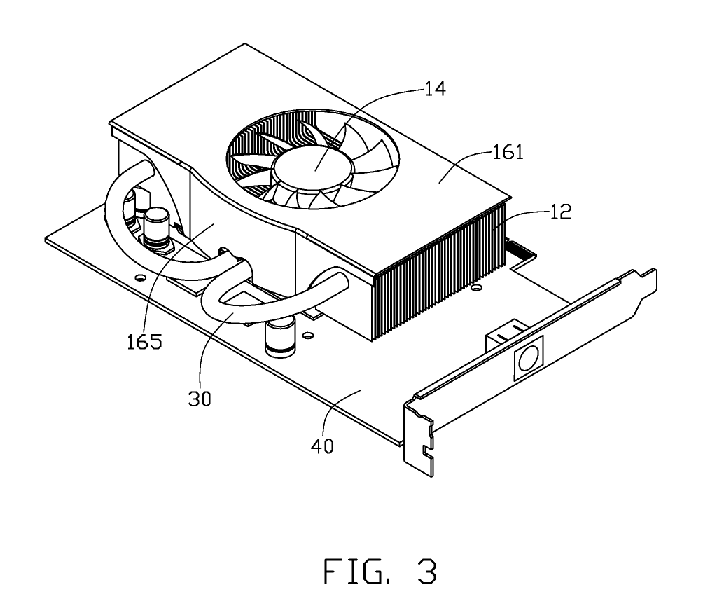

Referring to FIGS. 1-2, the cover 16 comprises a top plate 161 and two baffle plates 163, 165 extending perpendicularly and downwardly from opposite edges of the top plate 161. An arc portion (not labeled) is formed at a center of the baffle plate 165 (best seen in FIG. 3). A cutout 1652 is defined at a bottom of the baffle plate 165 to prevent the baffle plate 165 from interfering with the heat pipes 30 when the cover 16 and the heat pipes 30 are assembled together. A circular opening 167 is defined in the top plate 161 aligned with the fan 14. When assembled, the baffle plates 163, 165 are located at opposite sides of the fins 12 and clasp the fins 12 and cooperate with the shoulders 121, 123 to form a cavity for receiving the fan 14 therein. The baffle plates 163, 165 are located between the channels 1210.

The vapor chamber 20 is attached on the electronic component 42 and mounted on the graphics card 40 to absorb heat generated from the electronic component 42. The vapor chamber 20 has a flat type configuration and is rectangular shaped when viewed from above. The vapor chamber 20 comprises a rectangular shaped base plate 21, a top cover 23 on an opposite side of the vapor chamber 20 to the bottom plate 21. The base plate 21 and the top cover 23 are made of the materials having high thermal conductive capabilities, such as copper. The top cover 23 comprises a flat cover plate 231 parallel to the base plate 21 and four sidewalls 233 perpendicularly and downwardly extending from a periphery of the cover plate 231 and soldered to the base plate 21. Four counterbores 27 are defined in four corners of the vapor chamber 20, respectively, corresponding to the through holes 44 of the graphics card 40. Each counterbore 27 defines a first through hole (not labeled) in the top cover 23 and a smaller second though hole in the base plate 21. The top cover 23 downardly extends a respective annular sidewall (not labeled) surrounding each first through hole thereof. The vapor chamber 20 is enclosed to form a sealed cavity. Wick structures (not shown) are formed in the sealed vapor chamber 20 and work fluid (not shown) is contained in the vapor chamber 20. The vapor chamber 20 comprises a plurality of supporting posts (not shown) therein for supporting the top cover 23. The top cover 23 is located at the center of the bottom plate 21 and a flange 25 is formed between each side of the top cover 23 and the base plate 21. The vapor chamber 20 has a heating area (not labeled) contacting with the electronic component 42 mounted on the graphics card 40 and a cooling area (not labeled) except the heating area. The heating area absorbs the heat generated by the electronic component 42 and the cooling area transfers the heat to the fins 12 of the heat sink 10 and dissipates the heat into environment.

Each of the heat pipes 30 has a U-shaped configuration and comprises a flattened evaporating portion 32, a condensing portion 34 and an arc connecting portion 36 connecting with the evaporating portion 32 and the condensing portion 34. The flattened evaporating portion 32 has a flattened top plate and a bottom plate on an opposite side of the evaporating portion 32 to the top plate 161. The condensing portions 34 extend through the shoulders 121, 123 and are received in the channels 1210 of the heat sink 10; the evaporating portions 32 are received in the rectangular grooves 1270 and coplanar with the bottom surface of the fins 12.

The electronic assembly further comprises a back plate 50 for reinforcing the graphics card 40. The back plate 50 is positioned below a bottom side of the graphics card 40. The back plate 50 is cross-shaped and defines four through holes 52 therein and has four nuts 60.

Referring to FIG. 3, in assembly, four screws 70 extend through the counterbores 27 of the vapor chamber 20 and are coplanar with the cover plate 231 of the top cover 23 of the vapor chamber 20. Then, the top cover 23 of the vapor chamber 20 is received in the recess 127 of the fins 12 and the heat sink 10 is soldered onto the cover plate 231 of the top cover 23; simultaneously, the heat pipes 30 are received in the fins 12. In this state, the base plate 21 of the vapor chamber 20 is positioned below the bottom surface of the fins 12 and contacts with the electronic component 42 mounted on the graphics card 40; the evaporating portions 32 of the heat pipes 30 are sandwiched between the fins 12 of the heat sink 10 and the cover plate 231 of the top cover 23 of the vapor chamber 20 and the condensing portions 36 are fittingly received in the channels 1210 of the shoulders 121, 123 of the fins 12 of the heat sink 10. Therefore, the heat dissipation device 100 is assembled on the graphics card 40, and the heat pipes 30 are able to transfer the heat from the vapor chamber 20 to the fins 12. Then, the screws 70 extend through the through holes 44 of the graphics card 40, the through holes 52 of the back plate 50 and threadedly engage with the nuts 60 to fasten the back plate 50 to the graphics card 40. Thus, the heat dissipation device 100 is assembled on the graphics card 40.

In use of the heat dissipation device 100, the working fluid contained in the vapor chamber 20 moves from the heating area to the cooling area with a phase transition, i.e., from a liquid phase to a vapor phase, due to the heat absorbed from the electronic component 42. The vapor moves vertically upwardly to transfer the heat to the heat sink 10 via the cover plate 231 of the vapor chamber 20. Furthermore, the vapor moves horizontally to transfer the heat to the cooling area of the vapor chamber 10. The heat is therefore directly dissipated to the surrounding environment of the vapor chamber 20 and evenly transferred to the heat sink 10 at the top thereof, which further dissipates the heat to the surrounding environment. The heat pipes 30 transfer the heat to the heat sink 10. The fan 14 received in the cavity defined by the shoulders 121, 123 and the baffle plates 163, 165 directs airflow onto the heat sink 10 to reinforce heat dissipation efficiency of the heat dissipation device 100. Thus, the heat generated by the electronic component 42 is dissipated quickly.

It is believed that the present embodiments and their advantages will be understood from the foregoing description, and it will be apparent that various changes may be made thereto without departing from the spirit and scope of the invention or sacrificing all of its material advantages, the examples hereto described merely being preferred or exemplary embodiments of the invention.

What is claimed is:

1. A heat dissipation device adapted for dissipating heat generated by an electronic component mounted on an add-on card, comprising:
a vapor chamber adapted for being attached to the electronic component;
a heat sink comprising a plurality of fins, the fins directly contacting the vapor chamber and defining a recess at a bottom surface of the fins for receiving the vapor chamber therein; and
a heat pipe comprising an evaporating portion sandwiched between the vapor chamber and the fins of the heat sink, and a condensing portion extending through the fins.

2. The heat dissipation device of claim 1, wherein the vapor chamber defines a plurality of counterbores therein, screws extending through the counterbores, adapted for mounting the heat dissipation device on the add-on card.

3. The heat dissipation device of claim 2, wherein the vapor chamber comprises a base plate adapted for contacting with the electronic component mounted on the add-on card, a top cover hermetically covering the base plate and located at the center of the base plate and wick structures formed in the vapor chamber.

4. The heat dissipation device of claim 2 further comprising a back plate adapted to be mounted below the add-on card to engage with the screws for securing the heat dissipation device to the add-on card.

5. The heat dissipation device of claim 1, wherein the fins of the heat sink define a groove at a center of the bottom surface thereof, the evaporating portion of the heat pipe being received in the groove and having a flattened bottom face coplanar with the bottom surface of the fins.

6. The heat dissipation device of claim 1, wherein each of the fins of the heat sink comprises two shoulders extending upwardly from opposite ends thereof and a depressed portion located between the shoulders, the condensing portion of the heat pipe extending through a corresponding shoulder of each of the fins.

7. The heat dissipation device of claim 6, wherein one of the shoulders is cut away at a rear end of a lower portion thereof, adapted to prevent the fins from interfering with other components mounted on the add-on card.

8. The heat dissipation device of claim 6, wherein a cover is mounted onto the fins of the heat sink and comprises a top plate and two baffle plates extending downwardly from the opposite edges of the top plate and clasping the shoulders to define a cavity to receive a fan.

9. The heat dissipation device of claim 8, wherein an opening is defined in the top plate of the cover aligned with the fan.

10. The heat dissipation device of claim 6 further comprising an additional heat pipe comprising an evaporating portion sandwiched between the vapor chamber and the fins of the heat sink, and a condensing portion extending through the other shoulder of each of the fins.

11. The heat dissipation device of claim 1, wherein the heat pipe further comprises an arc connecting portion connecting with the evaporating portion and the condensing portion so as to have a U-shaped configuration.

12. An electronic assembly comprising:
an add-on card having an electronic component mounted thereon;
a heat dissipation device mounted on a first surface of the add-on card and thermally connecting with the electronic component, comprising:
a vapor chamber contacting with the electronic component; and
a plurality fins wherein a recess is defined at a bottom of the fins, the vapor chamber is received in the recess and the fins of the heat dissipation device are soldered to the vapor chamber; and
a back plate mounted on a second surface on an opposite side of the add-on card to the first surface;
wherein the vapor chamber and the back plate are connected together via a plurality of fasteners extending through the vapor chamber of the heat dissipation device to connect with the back plate.

13. The electronic assembly of claim 12, wherein the vapor chamber includes a top cover received in the recess of the heat sink and a base plate below the heat sink and wick structures formed in the vapor chamber.

13. The electronic assembly of claim 12, wherein the vapor chamber includes a top cover received in the recess of the heat sink and a base plate below the heat sink and wick structures formed in the vapor chamber.

15. The electronic assembly of claim 14, wherein each of the heat pipes has a U-shaped configuration.

16. An electronic assembly comprising:
an add-on card having a heat-generating electronic component thereon;
a vapor chamber mounted on the heat-generating electronic component;
a vapor chamber mounted on the heat-generating electronic component;
a heat pipe having an evaporating portion sandwiched between the heat sink and the vapor chamber and a condensing portion extending through the fins of the heat sink.

17. The electronic assembly of claim 16, wherein the heat sink defines a depressed portion receiving a fan therein.

18. The electronic assembly of claim 17, wherein the depressed portion is defined in a top of the heat sink.

19. The electronic assembly of claim 18 further comprising a back plate, wherein fasteners extend through the vapor chamber, the add-on card to connect with the back plate.
